(19) United States
(12) Patent Application Publication
(10) Pub. No.: US 2021/0082785 A1
(43) Pub. Date: Mar. 18, 2021

(54) SEMICONDUCTOR POWER DEVICE AND MANUFACTURING METHOD THEREOF

(71) Applicant: Dongguan Institute of Opto-Electroics, Peking University, Dongguan City (CN)

(72) Inventors: Zhiwen LIANG, Dongguan City (CN); Qi WANG, Dongguan City (CN); Qing WANG, Dongguan City (CN); Guoyi ZHANG, Dongguan City (CN)

(21) Appl. No.: 16/945,791

(22) Filed: Jul. 31, 2020

(30) Foreign Application Priority Data
Sep. 18, 2019 (CN) 201910880306.3

(51) Int. Cl. H01L 23/373; H01L 21/48; H01L 21/78

(52) U.S. Cl. CPC H01L 23/3732; H01L 21/78; H01L 21/4807

(57) ABSTRACT

A semiconductor power device includes a substrate, a power chip, and a capping layer, and the substrate has a patterned unit, and the thickness of the substrate is matched with the configuration of the power chip, and the height of the power chip is smaller than the thickness of the substrate, and the power chip is installed at a position corresponding to the patterned unit, and the capping layer is covered onto a side of the patterned unit having the substrate, and the power chip is covered by the capping layer and installed to the substrate. This invention features a simple structure and reasonable design. Since the height of the patterned unit is matched with the thickness of the power chip, therefore the height of the installed power chip is lower than the substrate to facilitate the installation of the capping layer and the dissipation of heat.

### FIELD OF THE INVENTION

The present invention relates to the technical field of semiconductor devices, and more particularly to a semiconductor power device and its manufacturing method.

### BACKGROUND OF THE INVENTION

As science and technology advance, new-generation semiconductor power devices have increasingly higher density and better performance, and the third-generation semiconductor power device represented by the gallium nitride (GaN) power device has shown its excellent applications of high power, high voltage and high density.

Research results indicate that the performance of semiconductor power devices is much higher than the physical limit performance of traditional power devices. The main reason is that the semiconductor power device generates and accumulate massive heat to increase the temperature of the device drastically while outputting large current, and the gallium nitride (GaN) and silicon carbide (SiC) power devices usually adopt conventional packaging technologies and come with a plastic package with a heat conductivity higher than those of the traditional power devices and give rise to a low thermal conductivity and a poor heat dissipation to limit the performance of the gallium nitride and silicon carbide power devices. As a result, the performance and reliability of the semiconductor power devices are reduced significantly, and the use of such devices is limited.

### SUMMARY OF THE INVENTION

In view of the drawbacks of the prior art, the present invention provides a semiconductor power device and its manufacturing method with the features of simple structure, reasonable design, good heat dissipating effect, and excellent performance to overcome the drawbacks of the prior art.

To achieve the aforementioned and other objectives, the present invention discloses a semiconductor power device, comprising a substrate, a power chip, and a capping layer, and the substrate has a patterned unit, and the thickness of the substrate is matched with the configuration of the power chip, and the height of the power chip is smaller than the thickness of the substrate, and the power chip is installed at a position corresponding to the patterned unit, and the capping layer is covered onto a side of the substrate having the patterned unit, and the power chip is covered by the capping layer and installed to the substrate.

Wherein, the substrate is made of a diamond material, and the capping layer is a diamond capping layer.

Wherein, the diamond material is a polycrystalline diamond material, a monocrystalline diamond material, a quasi-polycrystalline diamond material or any combination of the above.

Wherein, the substrate has an area of 0.1 mm²˜90000 mm², a thickness of 0.1 mm-80 mm, and a size matched with the configuration of the power device.

Wherein, the substrate is in a polygonal shape, a circular shape, or a triangular shape.

Wherein, the capping layer has a thickness of 0.1 mm-10 mm, and the thickness of the capping layer is matched with the configuration of the power chip.

Wherein, the power chip has a pin, and the pin comprises a source S, a drain D, and a gate G.

To achieve the aforementioned and other objectives, the present invention also discloses a manufacturing method of a semiconductor power device, and the manufacturing method comprises the following steps (Steps 1˜5).

Step 1: Prepare a substrate.

Step 2: Install a patterned unit on the substrate.

Step 3: Install a power chip, and engage a plurality of power chips into a plurality of chip units respectively.

Step 4: Install a pin protective film to a pin of the power chip.

Step 5: Install a capping layer, deposit a diamond material according to the height of the power chip to form a diamond capping layer to produce the power device.

In Step 1, a CVD method is used or a diamond powder is pressed to form a diamond substrate.

In Step 2, a semiconductor lithography, a physical compression or a laser manufacturing method is used to install a patterned unit on a side of the substrate and a plurality of chip units on the patterned unit.

In Step 3, a small amount of silver paste or high temperature solder paste is used to fix the power chip.

In Step 4, a semiconductor photoresist glue is used to install the protective film to the pin for protection.

In Step 5, a CVD process is used to deposit the diamond material on a side of the substrate having the patterned unit, so as to form the capping layer.

After the Step 5, the substrate is cut according to the distribution of the power chip by a laser, mechanical or etching method, and then the pin protective film is removed after the substrate is cut, so as to obtain an independently formed power device.

The present invention has the following advantageous effects:

1. The semiconductor power device of the present invention has a diamond material fully covered onto the power chip to overcome the heat accumulation problem of the silicon carbide and gallium nitride power device, and a diamond material with high thermal conductivity is used to fully cover and package the power device to improve the thermal conductive channels and dissipate the heat generated by the operation of the device to the outside quickly, so that the device is always situated at a relatively low operating temperature to achieve the best working performance of the device, and the present invention skillfully uses the diamond material with a very high thermal conductivity, and its heat dissipation performance is much better than other materials such as metals. The thermal conductivity of diamond is up to 2000 W/m·K (much higher than the thermal conductivity of copper which is equal to 380 W/m·K). The invention breaks through the traditional plastic packaging and the limitation of the traditional devices that cannot be used in an application with a temperature above 300° C. In addition, the semiconductor power device of the invention has the features of simple structure, reasonable design, good heat dissipation, and excellent performance.

2. The manufacturing method of the semiconductor power device of the present invention has the features of simple process and easy operation and meets the industrial manufacturing requirements, and the semiconductor power device manufactured by this method has good performance.

### BRIEF DESCRIPTION OF THE DRAWINGS

FIG. 1 is a schematic view of a semiconductor power device of the present invention;

FIG. 2a is a schematic view of a substrate of the present invention;

FIG. 2b is a cross-sectional view of a substrate of the present invention;

FIG. 3a is a schematic view of a substrate installed with a patterned unit in accordance with the present invention;

FIG. 3b is a cross-sectional view of a substrate installed with a patterned unit in accordance with the present invention;

FIG. 4a is a schematic view of a patterned substrate installed with a power chip in accordance with the present invention;

FIG. 4b is a cross-sectional view of a patterned substrate installed with a power chip in accordance with the present invention;

FIG. 5a is a schematic view of a power chip pin installed with a protective film in accordance with the present invention;

FIG. 5b is a cross-sectional view of a power chip pin installed with a protective film in accordance with the present invention;

FIG. 6a is a schematic view of a substrate deposited with a capping layer in accordance with the present invention;

FIG. 6b is a cross-sectional view of a substrate deposited with a capping layer in accordance with the present invention;

FIG. 7 is a schematic view of a power device to be cut in accordance with the present invention; and

FIG. 8 is a schematic view of a cut power device in accordance with the present invention.

Brief Description of Numerals Used in the Drawings: 1: Substrate; 2; Patterned unit; 3: Power chip; 4: Pin; 5: Chip unit; 6: Capping layer.

### DESCRIPTION OF THE PREFERRED EMBODIMENTS

The objectives, technical characteristics and effects of the present invention will become apparent with the detailed description of preferred embodiments accompanied with the illustration of related drawings. It is intended that the embodiments and drawings disclosed herein are to be considered illustrative rather than restrictive.

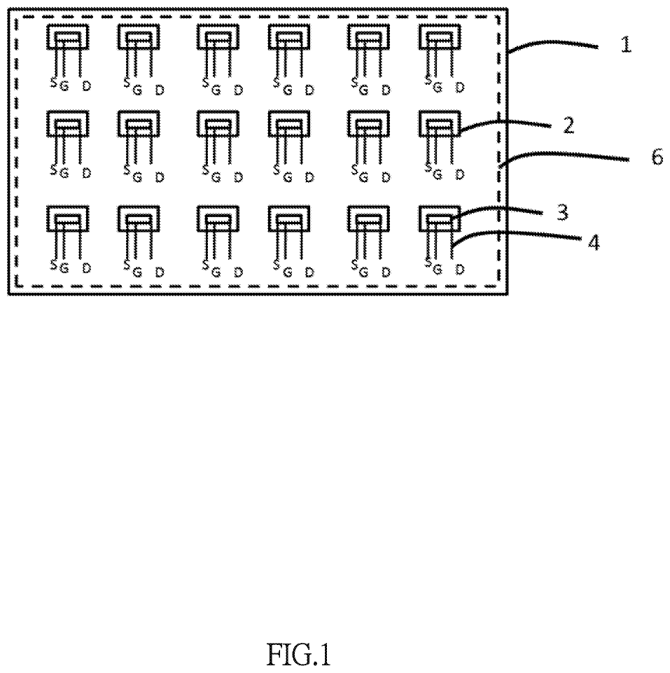

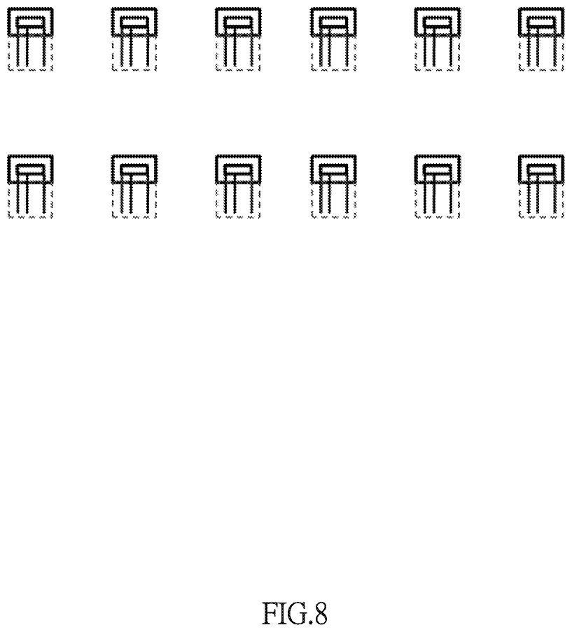

With reference to FIGS. 1 to 8 for a semiconductor power device in accordance with an embodiment of the present invention, the semiconductor power device comprises a substrate 1 and a power chip 3, and further comprises a capping layer 6, and the substrate has a patterned unit 2, and the thickness of the substrate 1 is matched with the configuration of the power chip 3, and the height of the power chip 3 is smaller than the thickness of the substrate 1, and the power chip 3 is installed at a position corresponding to the patterned unit 2, and the capping layer 6 is covered onto a side of the substrate 1 having the patterned unit 2, and the power chip 3 is covered by the capping layer 6 and installed to the substrate 1. The present invention has the features of simple structure and reasonable design. Since the height of the patterned unit is matched with the thickness of the power chip 3, therefore the height of the installed power chip 3 is lower than the substrate 1 to facilitate the installation of the capping layer 6 and the dissipation of heat and provide a good performance. The manufacturing method of the semiconductor power device has the features of simple process, and easy manufacturing, and the semiconductor power device manufactured by this method has a good heat dissipation effect.

The substrate 1 is made of a diamond material, and the thermal conductivity of diamond is up to 2000 W/m·K (much higher than the thermal conductivity of copper which is equal to 380 W/m·K). Therefore, the diamond material plays the role of a high-efficiency thermal conductive channel to further improve the heat dissipation performance of the present invention.

The diamond material is a polycrystalline diamond material, a monocrystalline diamond material, a quasi-polycrystalline diamond material, or any combination of the above. The substrate has an area of 0.1 mm2˜90000 mm2, a thickness of 0.1 mm-80 mm, and a size matched with the configuration of the power device, and the substrate 1 can be in a polygonal, circular or triangular shape which can be changed flexibly according to actual requirements to facilitate the application.

The capping layer 6 is a diamond capping layer 6 with a thickness of 0.1 mm-10 mm, and the thickness is matched with the configuration of the power chip. The structure is simple and the design is reasonable. The diamond capping layer 6 provides good thermal conduction and heat dissipation to ensure the heat dissipation and performance of the present invention.

The power chip 3 has a pin 4, and the pin 4 comprises a source S, a gate D and a gate G. The structure is simple and the design is reasonable. The power chip 3 can be connected to other components easily to facilitate the application.

The manufacturing method of the semiconductor power device comprises the following steps (S1 to S7).

Step 1: Prepare a substrate 1, wherein a CVD method or a diamond powder is pressed to form a diamond substrate 1.

Step 2: Install a patterned unit 2 on the substrate 1, wherein a semiconductor lithography, a physical compression, or a laser manufacturing method is used to install the patterned unit 2 on a side of substrate 1, and the patterned unit 2 has a plurality of chip units 5.

Step 3: Install a power chip 3, and engage a plurality of power chips 3 into a plurality of chip units 5 respectively, wherein a small amount of silver paste or high temperature solder paste process is used for curing;

Step 4: Install a protective film to a pin 4 of the power chip 3, wherein the protective film is installed to the pin 4 by using a semiconductor photoresist glue for protection.

Step 5: Install a capping layer 6, wherein a CVD process is used to deposit a diamond material on a side of the substrate 1 having the patterned unit 2, so as to form the capping layer 6.

Step 6: Cut the substrate 1, wherein the substrate 1 is cut according to the distribution of the power chips 3 by using a laser, mechanical or etching method.

Step 7: Remove the protective film, wherein the protective film of the pin 4 is removed, so that the diamond capping layer 6 deposited on the protective film falls off together with the protective film, and the pin 4 of the power chip 3 is exposed, and finally the power device is formed independently.

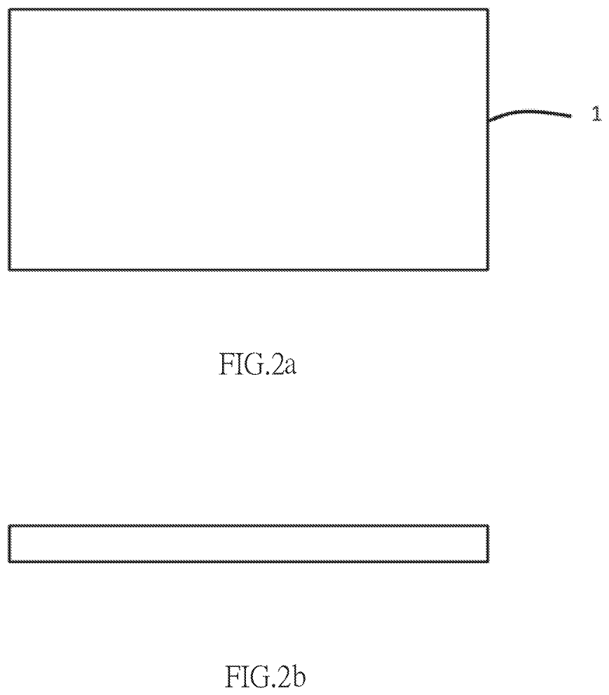

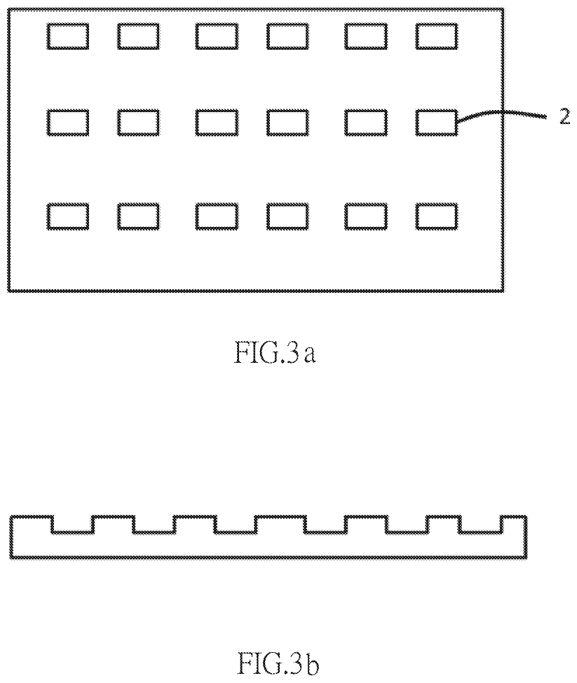

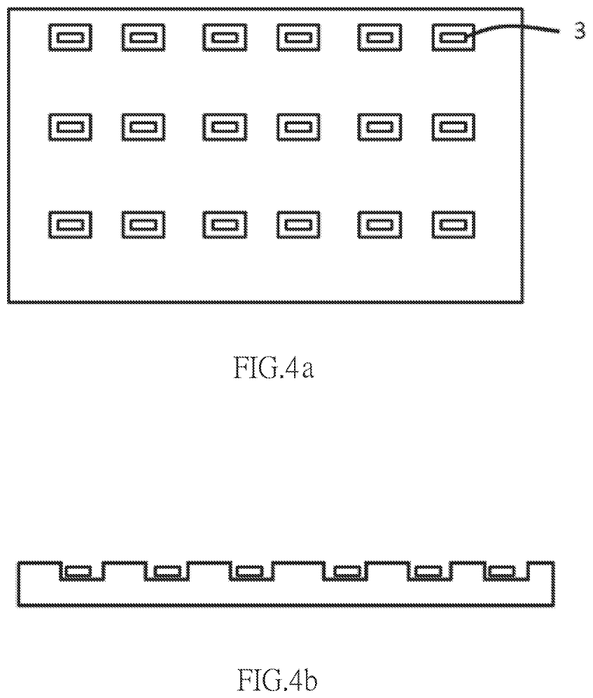

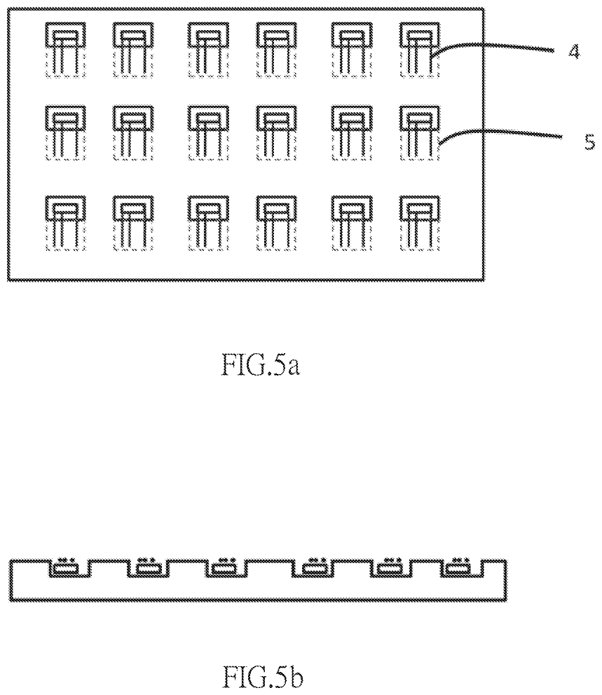

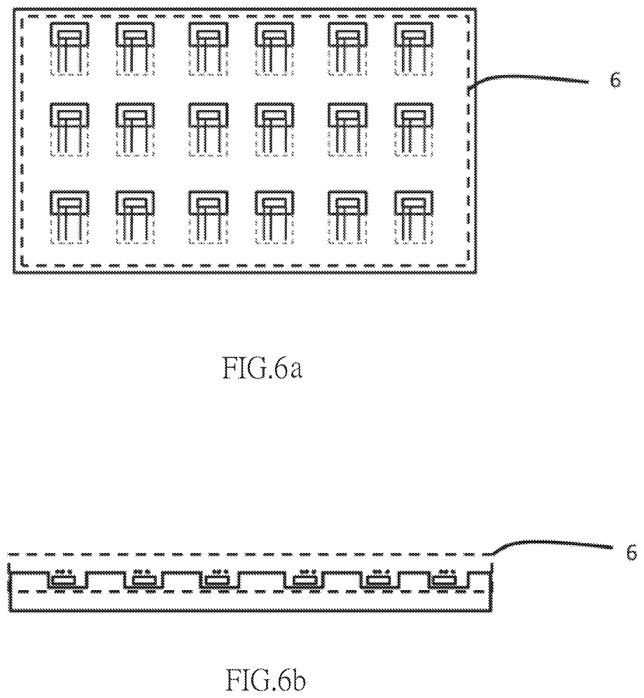

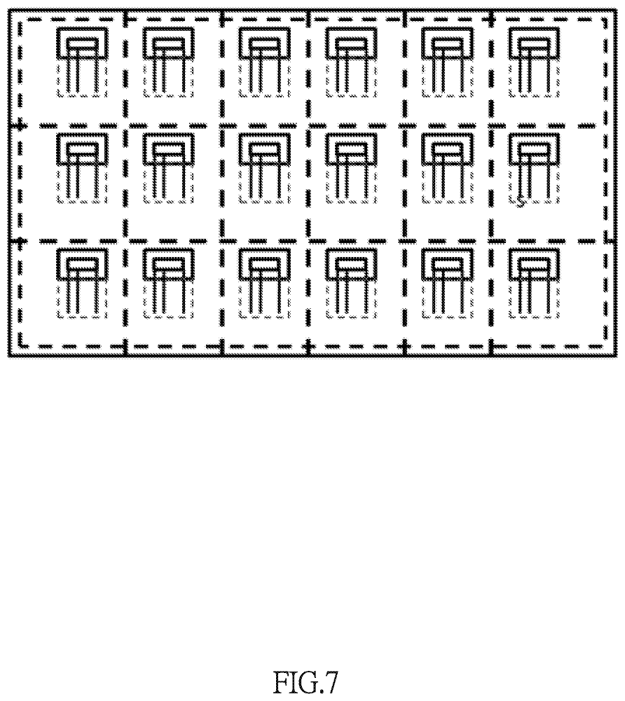

In summation, the manufacturing method of the present invention comprises the steps of preparing the diamond substrate 1, patternizing the substrate 1, laying the power chip 3, depositing a diamond capping layer, cutting and removing the film, etc. In FIG. 1, the diamond substrate 1 is prepared. In this embodiment, the substrate 1 has a length of 50 mm, a width of 50 mm, and a thickness of 1 mm. The substrate 1 is made of a material such as an insulating polycrystalline diamond and manufactured by an equipment such as a MPCVD by using methane as a source of carbon and passing in oxygen and hydrogen ions, wherein the polycrystalline diamond substrate 1 is prepared at the power of 4 KW, and the growth rate of 50 um/h, and deposited for 20 hours. In FIG. 2, a semiconductor lithography is used to patternize the polycrystalline diamond substrate 1, and the dimensions of the pattern are 3 mm*2 mm*0.5 mm. In FIG. 3, the power device chip is laid in the patterned unit 2, and the dimensions of the power chip 3 are 2 mm*1.5 mm*0.3 mm, and a small amount of silver paste is used for curing and fixing the power chip 3. In FIG. 4, a lead is formed on the diamond substrate 1 according to the distribution of the pin 4 of the power chip. In FIG. 5, a photoresist medium is used to protect the lead, and the polycrystalline diamond substrate 1 of the fixed chip is put into the MPCVD chamber again to perform the process of depositing the polycrystalline diamond capping layer, wherein the thickness is also 1 mm, and the whole piece of the substrate 1 and power chip 3 are deposited with the diamond capping layer 6 to achieve the effect of being fully covered and packaged by diamond. The power device can be cut if needed to prepare independent power devices as shown in FIG. 6. The whole piece of packaged substrate 1 is taken out from the MPCVD chamber, and then the substrate 1 is cut according to the layout of the power device chip. In FIG. 7, the substrate 1 is cut and divided into a plurality of independent units, and finally the protective film for protecting the leads is removed by a glue remover to expose the source S, drain D and gate G of the power device, so as to achieve the plastic-free high thermal conductive power device packaging, which can be used in a high temperature application environment. The invention has the features of simple process and easy manufacturing, and the semiconductor power device manufactured by the manufacturing method of this invention provides high performance and good application.

While the invention has been described by means of specific embodiments, numerous modifications and variations could be made thereto by those skilled in the art without departing from the scope and spirit of the invention as set forth in the claims.

What is claimed is:

1. A semiconductor power device, comprising a substrate and a power chip,
characterized in that the semiconductor power device further comprises a capping layer, and the substrate has a patterned unit, and the substrate has a thickness matched with the configuration of the power chip, and the power chip has a height smaller than the thickness of the substrate, and the power chip is installed and configured to be corresponsive to the patterned unit, and the capping layer is covered onto a side of the substrate having the patterned unit, and the power chip is covered by the capping layer and then installed to the substrate.

2. The semiconductor power device as claimed in claim 1, wherein the substrate is made of a diamond material, and the capping layer is a diamond capping layer.

3. The semiconductor power device as claimed in claim 2, wherein the diamond material is one selected from the group consisting of a polycrystalline diamond material, a monocrystalline diamond material and a quasi-polycrystalline diamond material, or one or more combinations thereof.

4. The semiconductor power device as claimed in claim 1, wherein the substrate has an area of 0.1 mm²˜90000 mm², a thickness of 0.1 mm-80 mm, and a size matched with the configuration of the power device.

5. The semiconductor power device as claimed in claim 1, wherein the substrate is in a shape selected from the group consisting of a polygonal shape, a circular shape, and a triangular shape.

6. The semiconductor power device as claimed in claim 1, wherein the capping layer has a thickness of 0.1 mm-10 mm, and the thickness of the capping layer is matched with the configuration of the power chip.

7. The semiconductor power device as claimed in claim 1, wherein the power chip has a pin, and the pin comprises a source S, a drain D, and a gate G.

8. A manufacturing method of the semiconductor power device as claimed in any one of claim 1, comprising the steps of:
(Step 1) preparing a substrate;
(Step 2) installing a patterned unit on the substrate;
(Step 3) installing a power chip, engaging a plurality of power chips into a plurality of chip units respectively;
(Step 4) installing a pin protective film to a pin of the power chip; and
(Step 5) installing a capping layer, depositing a diamond material according to the height of the power chip to form a diamond capping layer to produce the power device.

9. The manufacturing method of a semiconductor power device as claimed in claim 8, wherein a CVD method is used or a diamond powder is pressed to form a diamond substrate in the Step 1; a semiconductor lithography, a physical compression or a laser manufacturing method is used to install a patterned unit on a side of the substrate and a plurality of chip units on the patterned unit in the Step 2; a small amount of silver paste or high temperature solder paste is used to fix the power chip in the Step 3; a semiconductor photoresist glue is used to install the protective film to the pin for protection in the Step 4; a CVD process is used to deposit the diamond material on a side of the substrate having the patterned unit, so as to form the capping layer in the Step 5.

10. The manufacturing method of a semiconductor power device as claimed in claim 8, wherein after the Step 5, the substrate is cut according to the distribution of the power chip by a laser, mechanical or etching method, and then the pin protective film is removed after the substrate is cut, so as to obtain an independently formed power device.
